(19) United States
(12) Patent Application Publication
(10) Pub. No.: US 2012/0037502 A1
(43) Pub. Date: Feb. 16, 2012

(54) Sintered Body for ZnO-Ga2O3-Based Sputtering Target and Method of Producing the Same

(75) Inventors: Satsuki Nagayama, Chiba (JP); Kaoru Satonosono, Chiba (JP)

(73) Assignee: ULVAC, INC., Kanagawa (JP)

(21) Appl. No.: 13/265,572

(22) PCT Filed: Apr. 27, 2010
(86) PCT No.: PCT/JP2010/003001

§ 371 Date: Oct. 21, 2011

(30) Foreign Application Priority Data
May 1, 2009 (JP) 2009-111757

(51) Int. Cl. C23C 14/08; C04B 35/453

(52) U.S. Cl. 204/298.13; 264/607

(57) ABSTRACT

[Object] To provide a sintered body for a ZnO—Ga₂O₃-based sputtering target, which has a low resistivity and is capable of suppressing the formation of nodules and flakes, and a method of producing the same.

[Solving Means] The present invention includes the steps of forming a powder mixture of a zinc oxide powder and a gallium oxide powder, housing the compact of the powder mixture in an inside of a container 20 to be installed in an inside of a sintering furnace 10, raising a temperature of the compact up to a sintering temperature of not less than 1200° C. but not more than 1500° C. while introducing oxygen into the inside of the container 20, keeping the sintering temperature under a state in which the oxygen is introduced into the inside of the container 20, and lowering a temperature of the inside of the furnance under a state in which the introduction of the oxygen into the inside of the container 20 is stopped. The container 20 has a function to be heated within the furnace to achieve a homogenization of a heat distribution of the compact, and hence it is possible to eliminate an influence due to the heat distribution within the furnace and to improve a property of evenly heating the compact. Thus, it is possible to obtain the GZO sputtering target having the low resistivity and capable of suppressing the formation of nodules.

### TECHNICAL FIELD

The present invention relates to a sintered body for a ZnO—Ga₂O₃-based sputtering target, which is capable of suppressing the formation of nodules and flakes, and a method of producing the same.

### BACKGROUND ART

As a transparent conductive film to be used in an electrode layer of a liquid crystal display or a solar cell, a ZnO—Ga₂O₃-based (hereinafter, also referred to as GZO) film has been being developed. The GZO film is formed by sputtering. Thus, in order to perform stable sputtering, a homogeneous GZO sputtering target (hereinafter, also abbraviated as GZO target) having a high relative density and a low resistivity is required.

The GZO target can be produced in such a manner that a powder mixture of a zinc oxide powder and a gallium oxide powder is sintered. Further, by reducing the resulting sintered body, the GZO target having a low resistivity can be produced. However, with the GZO target obtained by sintering the compact in the atmosphere, the sintered body cannot be evenly reduced due to an influence of a temperature distribution within the sintering furnace. Therefore, the resulting sintered body has a locally large variation in resistivity value. Thus, when such a sintered body is used as the sputtering target, many nodules and flakes are formed in the surface of the target, which leads to a problem that stable sputtering cannot be performed.

On the other hand, Patent Document 1 below discloses a method of producing a GZO sintered body, which includes forming the powder mixture of the zinc oxide powder and the gallium oxide powder, sintering the compact while introducing oxygen at the temperature of from 1300 to 1550° C., and reducing it in non-oxidizing gas atmosphere after sintering. It is said that according to this method, it is possible to obtain the GZO target having a high relative density and a relatively low resistivity (volume resistivity: 2×10⁻² Ω·cm or less).

### CITED DOCUMENT

### Patent Document

Patent Document 1: Japanese Patent Application Laid-open No. HEI 10-297962 (paragraphs [0015], [0016])

### DISCLOSURE OF THE INVENTION

### Problem to be solved by the Invention

However, in the method of producing the GZO target disclosed in Patent Document 1 above, there is merely described that the volume resistivity in the depth direction is 2×10⁻² Ω·cm, and no mention is made of the distribution of the resistivity. Thus, it is unclear whether or not the formation of nodules and flakes can be suppressed when the resulting sintered body is used as the sputtering target.

In the above-mentioned circumstances, it is an object of the present invention to provide a sintered body for a ZnO—Ga₂O₃-based sputtering target, which has a low resistivity and is capable of suppressing the formation of nodules and flakes, and a method of producing the same.

### Means for Solving the Problem

In order to achieve the above-mentioned object, a method of producing a sintered body for a ZnO—Ga₂O₃-based sputtering target according to an embodiment includes a step of forming a powder mixture of a zinc oxide powder and a gallium oxide powder. The compact of the powder mixture is housed in an inside of a container to be installed in an inside of a sintering furnace. A temperature of the compact is raised up to a sintering temperature of not less than 1200° C. but not more than 1500° C. while introducing oxygen into the inside of the container. The sintering temperature is kept under a state in which the oxygen is introduced into the inside of the container. A temperature of the inside of the furnance is lowered under a state in which the introduction of the oxygen into the inside of the container is stopped.

A sintered body for a ZnO—Ga₂O₃-based sputtering target according to an embodiment includes a sintered body of a powder mixture of a zinc oxide powder and a gallium oxide powder. The above-mentioned sintered body has a relative density of 98% or more, an average grain diameter of 50 μm or less, and a resistivity of 2×10−3 Ω·cm or less.

### BRIEF DESCRIPTION OF DRAWINGS

FIG. 1 A flowchart describing a method of producing a sintered body for a ZnO—Ga₂O₃-based sputtering target according to an embodiment of the present invention.

FIG. 2 A view of a schematic configuration of a sintering furnace for producing a sintered body.

FIG. 3 A perspective view showing a configuration of a container installed in the inside of the sintering furnace.

FIG. 4 A view showing experiment results of Examples of the present invention.

FIG. 5 A view describing other experiment results of Examples of the present invention.

### BEST MODE(S) FOR CARRYING OUT THE INVENTION

A method of producing a sintered body for a ZnO—Ga₂O₃-based sputtering target according to an embodiment includes a step of forming a powder mixture of a zinc oxide powder and a gallium oxide powder. The compact of the powder mixture is housed in an inside of a container to be installed in an inside of a sintering furnace. A temperature of the compact is raised up to a sintering temperature of not less than 1200° C. but not more than 1500° C. while introducing oxygen into the inside of the container. The sintering temperature is kept under a state in which the oxygen is introduced into the inside of the container. A temperature of the inside of the furnance is lowered under a state in which the introduction of the oxygen into the inside of the container is stopped.

In the method of producing the sintered body, the compact is sintered in the inside of the container installed in the inside of the sintering furnace. The container has a function to be heated within the furnace to achieve a homogenization of a heat distribution of the compact. According to this method, it is possible to eliminate an influence due to the heat distribution within the furnace and to improve a property of evenly heating the compact. Thus, it is possible to produce the sintered body having a small variation in resistivity value. Further, it is possible to provide the GZO sputtering target capable of suppressing the formation of nodules and flakes.

The sintering temperature is set to be not less than 1200° C. but not more than 1500° C., and hence it is possible to produce the sintered body for the GZO target having an average grain diameter of 50 μm or less and a relative density of 98% or more. If the sintering temperature is less than 1200° C., the sintering cannot be promoted, and thus it is difficult to obtain the desired relative density. Further, if the sintering temperature exceeds 1500° C., grain coarsening occurs, and thus it is difficult to obtain the high density.

During temperature-raising, the oxygen functioning as a sintering aid is introduced into the inside of the container, and hence it is possible to promote the growth of the powder particles, to prevent evaporation of Zn due to the oxygen loss, and to increase the sintered density. As described above, the compact is housed in the inside of the container, and the sintering is performed while introducing the oxygen into the inside of the container. Thus, it becomes possible to evenly supply the oxygen to the entire surface of the compact, and to produce an evenly sintered body.

During temperature-lowering, the introduction of the oxygen into the inside of the container is stopped, and hence the reduction of the sintered body is promoted and homogeneous oxygen loss of the sintered body is caused. The reduction process of the sintered body is performed in the inside of the container, and hence the sintered body can be evenly reduced. With this, it becomes possible to obtain the GZO target having a low resistivity of 2×10⁻³ Ω·cm or less and a variation in resistivity of 20% or less. Here, the resistivity means a volume resistivity.

The above-mentioned container can be made of a ceramics material having thermal resistance, such as an alumina or a zirconia. The size of the container is not particularly limited, and may depend on the size of the compact.

A flow rate of the oxygen to be introduced into the inside of the container is set to be 20 L/min or less, and hence it is possible to stably produce the GZO target having the above-mentioned characteristics. If the oxygen introducing amount exceeds 20 L/min, the oxygen containing amount becomes excessively large, and thus, it is difficult to obtain a desired low resistivity characteristic. Further, although the lower limit of the oxygen introducing amount can be appropriately set, the oxygen introducing amount can be, for example, 1 L/min or more in order to effectively obtain the function as the sintering aid.

A mixing ratio of the gallium oxide powder may be 2 wt % or less. With this, it is possible to stably produce the GZO target having a low resistivity.

The container may include a plurality of containers installed in the inside of the sintering furnace. In this case, compacts each housed in the plurality of containers are sintered simultaneously. With this, it is possible to efficiently produce the GZO target having the desired characteristics.

A sintered body for a ZnO—Ga₂O₃-based sputtering target according to an embodiment includes a sintered body of a powder mixture of a zinc oxide powder and a gallium oxide powder. The above-mentioned sintered body has a relative density of 98% or more, an average grain diameter of 50 μm or less, and a resistivity of 2×10−3 Ω·cm or less.

With this, it is possible to provide the GZO sputtering target capable of suppressing the formation of nodules and flakes. Further, the resistivity is significantly low, specifically, than 2×10⁻³ Ω·cm or less, and hence it becomes possible to form a GZO thin film having a low resistivity.

Hereinafter, an embodiment of the present invention will be described with reference to the drawings.

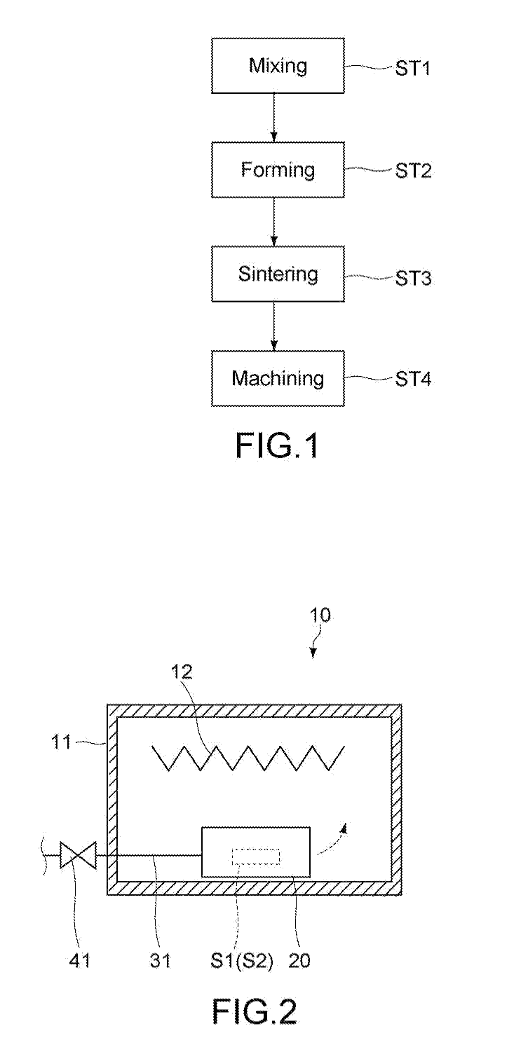

FIG. 1 is a flowchart describing a method of producing a sintered body for a ZnO—Ga₂O₃-based sputtering target (hereinafter, also referred to as GZO target) according to the embodiment of the present invention. The method of producing the GZO target according to this embodiment includes a mixing step ST1 for raw material powders, a forming step ST2 for a powder mixture, a sintering step ST3 for a compact, and a contour machining step ST4 for the sintered body.

[Mixing Step]

As the raw material powders, a zinc oxide (ZnO) powder and a gallium oxide (Ga₂O₃) powder are used. The average grain diameter of the zinc oxide powder is 1 μm or less, and the average grain diameter of the gallium oxide powder is 1.5 μm or less. However, the grain diameter is not limited thereto. In the mixing step ST1, the powder mixture of those raw material powders is prepared.

In the mixing step, the zinc oxide powder and the gallium oxide powder are mixed together in a predetermined ratio. Although the mixing ratio is not particularly limited, in this embodiment, the mixing ratio of the gallium oxide powder is adjusted to 2 wt % or less. With this, it is possible to produce the sintered body for the GZO target, which has a low resistivity. For mixing of the raw material powders, various mixing methods can be employed. Further, in mixing of the raw material powders, a binder, a dispersant, and the like may be added.

[Forming Step]

Next, the step of forming the resulting powder mixture into a predetermined shape is performed (ST2). For forming of the powder mixture, a cold forming method such as a cold press or a cold isostatic press (CIP) can be employed. The forming pressure is not particularly limited, and, for example, is 1 ton/cm² or more. The shape is also not particularly limited, and the powder mixture is formed into an appropriate shape such as a plate shape or a block shape.

[Sintering Step]

Subsequently, the step of sintering the resulting compact is performed (ST3). In the sintering step, the compact is housed in the inside of the container installed in the inside of the sintering furnace, and is sintered in the inside of the container. FIG. 2 is a sectional view showing a schematic configuration of the sintering furnace.

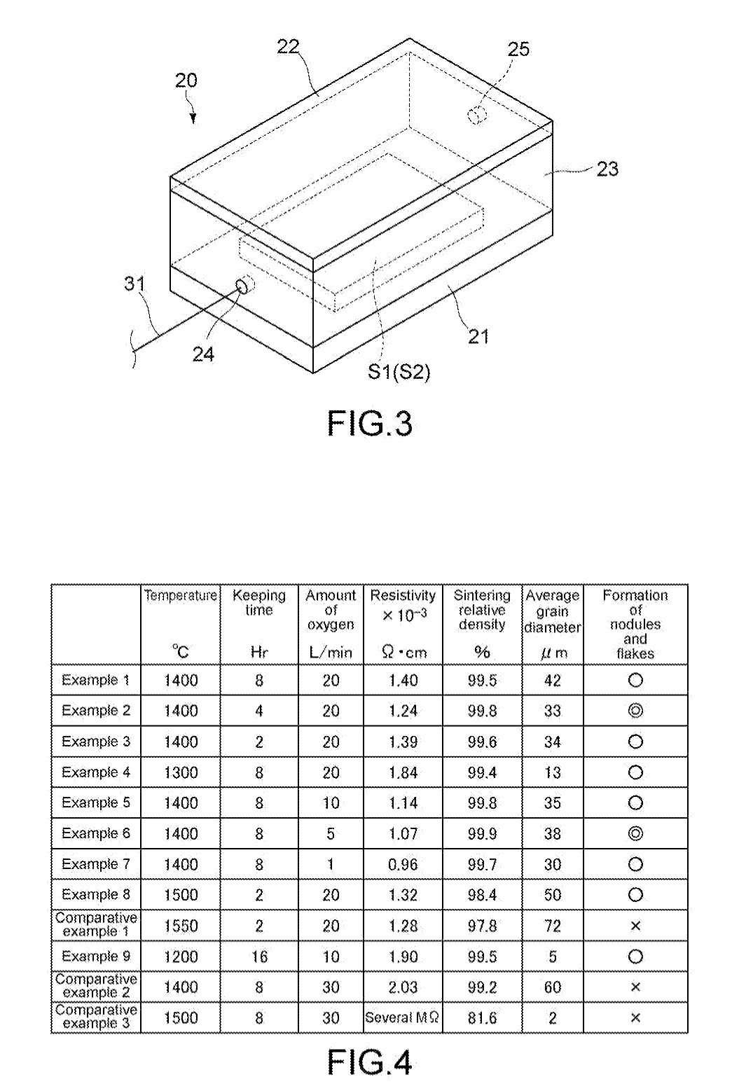

As shown in FIG. 2, the sintering furnace 10 includes a furnace main body 11 and a heater 12 serving as a heat source. The container 20 is installed in the inside of the furnace main body 11, and the compact S1 is housed in the inside of the container 20. To the container 20, piping 31 including an on-off valve 41 is connected. The piping 31 extends through the furnace main body 11 and is connected to an oxygen supply source (not shown). The piping 31 constitutes an oxygen introduction line for introducing the oxygen into the inside of the container 20 during sintering of the compact S1. The oxygen introduced into the inside of the container 20 is discharged through a hole 25 (FIG. 3) formed in the container 20. To the furnace main body 11, a discharge means for discharging the discharged oxygen to the outside of the furnace.

FIG. 3 is a perspective view showing a configuration of the container 20. The container 20 is made of a material having air tightness and thermal resistance. The container 20 includes a setter 21, four side walls 23, and a lid 22. Those materials may be made of an alumina fiber, a zirconia fiber, a MgO brick, or the like. In two opposed side walls of the four side walls 23, a first hole 24 and a second hole 25 are formed, respectively. The first hole 24 serves as a connection hole with respect to the piping 31. The second hole 25 serves to discharge the oxygen introduced into the inside of the container 20 to the outside of the container 20. The hole 25 is not limited to a single hole, and a plurality of holes may be formed. The container 20 may be always installed in the inside of the sintering furnace 10, or may be removable with respect to the sintering furnace 10. Further, the shape and size of the container 20 are not particularly limited, and are appropriately set depending on the size of the compact S1.

The sintering step includes a temperature raising step, a keeping step, and a temperature lowering step. In the temperature raising step, the container 20 and the compact S1 are heated at a predetermined temperature raising speed while introducing the oxygen into the inside of the container 20 at the same time. In the keeping step, the temperature-raising is stopped at a predetermined sintering temperature, and that temperature is kept for a predetermined period of time. Also in this keeping step, the introduction of the oxygen into the inside of the container 20 is continued. In the temperature lowering step, the introduction of the oxygen into the inside of the container 20 is stopped, and the container 20 and the compact S1 are cooled down to nearly room temperature within the furnace.

Hereinafter, the sintering step will be described in detail.

After the compact S is housed in the inside of the container 20, the heater 12 heats the inside of the furnace. At this time, the oxygen is introduced into the inside of the container 20 at a predetermined flow rate through the piping 31, and at the same time, the oxygen is discharged through the hole 25. That is, the container 20 is kept in the oxygen gas atmosphere, and at the same time, the container 20 and the compact S1 are heated up to a predetermined temperature. During temperature-raising, the oxygen functioning as a sintering aid is introduced into the inside of the container 20, and hence it is possible to promote the growth of the powder particles, to prevent evaporation of Zn due to the oxygen loss, and to increase the sintered density.

The temperature raising speed is not particularly limited, and is appropriately set depending on the sintering temperature of the compact S1. The temperature raising speed may be varied depending on the temperature range. For example, the temperature raising speed is set to be 1° C./min from the room temperature to 1000° C., and 3° C./min from 1000 to 1500° C. The temperature raising speed is increased in the high temperature range, and hence it becomes possible to suppress evaporation of the oxygen from the compact S1, and at the same time, to obtain the sintered body having a high relative density.

The flow rate of the oxygen to be introduced into the inside of the container 20 may be, for example, not less than 1 L/min but not more than 20 L/min. If the introduced amount is less than 1 L/min, the effect as the sintering aid becomes smaller, and thus, the sintering of the compact S1 cannot be promoted. Further, if the introduced amount exceeds 20 L/min, an oxygen amount contained in the resulting sintered body becomes excessively large, and thus, it is difficult to obtain the desired low resistivity characteristic. The oxygen introduced into the inside of the container 20 is discharged through the hole 25 to the outside of the container 20. The inner pressure of the container 20 is kept at the atmospheric pressure.

At a point in time when the temperature within the furnace reaches a predetermined sintering temperature, the temperature-raising is stopped and that sintering temperature is kept. Also in this keeping step, the introduction of the oxygen into the inside of the container 20 is continued. This can suppress a variation in an oxygen supplying amount with respect to the compact S1 with a result that an evenly sintering process proceeds.

In this embodiment, as described above, the compact S1 is housed in the inside of the container 20 installed in the inside of the sintering furnace 10, and the sintering process of the compact S1 is performed in the inside of the container 20. The container 20 is heated in the inside of the sintering furnace 10, and functions as a heat generator for the compact S1. The container 20 has a volume smaller than that of the furnace, and hence it is possible to achieve a homogenization of the heat distribution with respect to the compact S1 housed in the inside of the container 20. This can eliminate the influence of the heat distribution within the sintering furnace 10, and hence the entire compact S1 is evenly heated without generating the heat distribution with respect to the compact S1.

The sintering temperature is set to be not less than 1200° C. but not more than 1500° C. If the sintering temperature is less than 1200° C., the sintering cannot be promoted, and thus it is difficult to obtain the desired relative density. If the sintering temperature exceeds 1500° C., grain coarsening occurs, and thus it is difficult to obtain the high density.

The keeping period of time can be appropriately set depending on the sintering temperature and the like. If the sintering temperature is low, the keeping temperature is set to be longer. In contrast, if the sintering temperature is high, the keeping temperature is set to be shorter. If the sintering temperature ranges from 1200° C. to 1500° C., the keeping period of time can be set to be not less than 2 hours but more than 20 hours, for example.

After a predetermined keeping period of time is elapsed, the introduction of the oxygen into the inside of the container 20 is stopped, and at the same time, the temperature of the inside of the sintering furnace 10 is lowered. The introduction of the oxygen into the inside of the container 20 is stopped during temperature-lowering, and hence the reduction of the sintered body S2 is promoted, which leads to homogeneous oxygen loss of the sintered body S2. The reduction process of the sintered body S2 is performed in the inside of the container 20, and hence the sintered body S2 can be evenly reduced. In this manner, it is possible to obtain the GZO target having a low resistivity of 2×10⁻³ Ω·cm or less and a variation in resistivity of 20% or less.

The temperature-lowering speed of the furnace is not particularly limited, and can be set to 100° C./hour or less, for example. If the temperature-lowering speed is excessively high, there is a fear that cracks are formed in the sintered body S2. Further, as the temperature-lowering speed becomes smaller, the productivity becomes lower, but the reduction process of the oxygen can be continued for a long period, and hence it becomes possible to obtain the sintered body having the low resistivity.

[Machining Step]

After the sintered body S2 is produced, the sintered body S2 is mechanically processed to have a desired target size (ST4). Although the machining shape is typically a rectangular or circular shape, it is needless to say that the machining shape is not limited thereto.

As described above, the sintered body for the GZO target is produced. According to this embodiment, it is possible to obtain the GZO target having the relative density of 98% or more, the average grain diameter of 50 μm or less, and the resistivity of 2×10⁻³ Ω·cm or less. Thus, it is possible to constitute the GZO target capable of suppressing the formation of nodules and flakes.

### EXAMPLES

### Example 1

The zinc oxide (ZnO) powder and the gallium oxide (Ga₂O₃) powder as the raw material powders were mixed together in a ratio by weight of 99.4:0.6. The average grain diameter of the zinc oxide powder was set to 0.1 μm, and the average grain diameter of the gallium oxide powder was set to 1.3 μm. Those raw material powders were put in a pot made of a resin, and the powder mixture was prepared using wet ball milling. Here, a zirconia ball was used as a ball of the ball mill, a polyacrylamide-based (2 wt %) binder was used as a binder, and the mixing period of time was set to 24 hours. After mixing, the slurry was removed, dried, and granulated.

The granulated powder mixture was subjected to the cold isostatic press (CIP), to thereby produce the compact of 420 mm vertical, 390 mm horizontal, and 30 mm thickness. The pressure for formation was set to 2 ton/cm². After that, the resulting compact was degreased at 600° C. for 3 hours.

Next, the hermetically sealed container as shown in FIG. 2 and FIG. 3 was prepared. The inside dimension of the container was set to 700 mm vertical, 430 mm horizontal, and 100 mm tall. The resulting compact was housed in the inside of the container, and the container was installed in the inside of the sintering furnace. Then, the sintering process with respect to the compact was performed. The inside dimension of the sintering furnace was set to 1400 mm vertical, 850 mm horizontal, and 500 mm tall. The sintering temperature was set to 1400° C. First, the oxygen was introduced into the inside of the container, and at the same time, the temperature of the inside of the furnance was raised. The temperature raising speed was set to 1° C./min up to 1000° C., and to 2° C./min from 1000° C. to 1400° C. The oxygen introducing amount was set to 20 L/min. After reaching the sintering temperature (1400° C.), that temperature was kept for 8 hours. During this keeping step, the oxygen at the same flow rate was continued to be introduced into the inside of the container. After the keeping period of time was elapsed, the introduction of the oxygen into the inside of the container was stopped, and then, the temperature of the inside of the furnance was lowered with the inside of the container being kept at the atmospheric pressure. The temperature-lowering speed was set to 50° C./hour.

With respect to the resulting sintered body, the sintered density (relative density), the average grain diameter, and the resistivity (volume resistivity) were measured. The sintered density was culculated in such a manner that after the sintered body was machined by means of a surface grinder, the dimension and weight thereof were calculated, to thereby obtain a sintered density as a relative ratio with respect to a theoretical density (in this case, 5.66 g/cm³). The average grain diameter was measured in such a manner that after the sintered body was subjected to mirror polishing, the polished surface was etched with dilute nitric acid, and a grain boundary was formed, an observation using a scanning electron microscope (SEM) was performed. The resistivity was obtained by cutting the sintered body and measuring its cut surface by a four probe method. As a result, the resistivity was 1.4×10⁻³ Ω·cm, the relative density was 99.5%, and the average grain diameter was 42 μm.

The resulting sintered body was subjected to a grinding process, as a target for sputtering. The target is bonded onto a backing plate made of copper at 180° C. For a brazing material, an indium was used. The target bonded on the backing plate was incorporated in a cathode of a sputtering apparatus, and then subjected to sputtering. Such a sputtering condition that the deposition pressure was 0.4 Pa, the voltage was 560V, the current was 20 A, and the process gas (Ar) was 75 sccm was employed, and the sputtering period of time was set to 100 kWh.

After that, the chamber was opened, and the surface state of the target was observed. The 3-grade evaluation of a double circle mark, a single circle mark, and a cross mark was employed. Here, when a significantly large number of nodules and flakes were observed, the “cross mark” was set. When some nodules and flakes were observed, but it was durable for use, the “single circle mark” was set. When few nodules and flakes were observed, the “double circle mark” was set. The evaluation result is shown in FIG. 4.

### Example 2

Except for setting the sintering keeping period of time to be 4 hours, the same condition as in Example 1 was used to reproduce the sintered body. The resistivity of the resulting sintered body was 1.24×10⁻³ Ω·cm, the relative density was 99.8%, and the average grain diameter was 33 μm. This sintered body was used to manufacture the target, the sputtering test similar to Example 1 was carried out. The evaluation result is shown in FIG. 4.

### Example 3

Except for setting the sintering keeping period of time to be 2 hours, the same condition as in Example 1 was used to reproduce the sintered body. The resistivity of the resulting sintered body was 1.39×10⁻³ Ω·cm, the relative density was 99.6%, and the average grain diameter was 34 μm. This sintered body was used to manufacture the target, the sputtering test similar to Example 1 was carried out. The evaluation result is shown in FIG. 4.

### Example 4

Except for setting the sintering temperature to be 1300° C., the same condition as in Example 1 was used to reproduce the sintered body. The resistivity of the resulting sintered body was 1.84×10⁻³ Ω·cm, the relative density was 99.4%, and the average grain diameter was 13 μm. This sintered body was used to manufacture the target, the sputtering test similar to Example 1 was carried out. The evaluation result is shown in FIG. 4.

### Example 5

Except for setting the oxygen introducing amount to be 10 L/min, the same condition as in Example 1 was used to reproduce the sintered body. The resistivity of the resulting sintered body was 1.14×10⁻³ Ω·cm, the relative density was 99.8%, and the average grain diameter was 35 μm. This sintered body was used to manufacture the target, the sputtering test similar to Example 1 was carried out. The evaluation result is shown in FIG. 4.

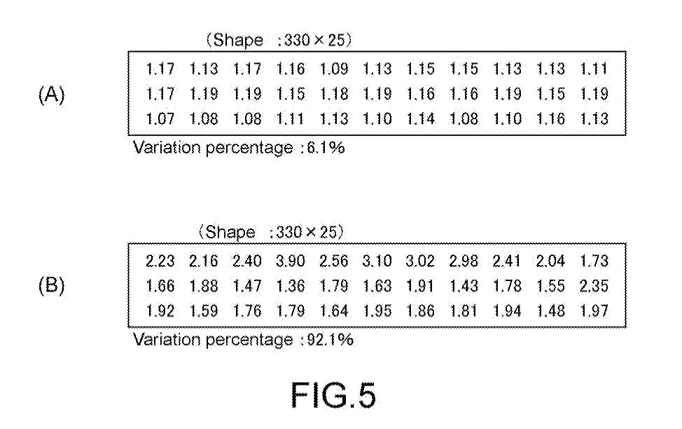

Further, the sintered body was cut in the thickness direction, and the distribution of the resistivity in the cut surface was measured in a range of 330 mm horizontal and 25 mm thickness. The results are shown in FIG. 5(A). It was confirmed that the variation percentage was 6.1% and thus the resistivity was substantially evenly distributed. It should be noted that the variation percentage was calculated by subtracting an average value from a difference between the maximum value and the minimum value of the resistivity at each point.

### Example 6

Except for setting the oxygen introducing amount to be 5 L/min, the same condition as in Example 1 was used to reproduce the sintered body. The resistivity of the resulting sintered body was 1.07×10⁻³ Ω·cm, the relative density was 99.9%, and the average grain diameter was 38 μm. This sintered body was used to manufacture the target, the sputtering test similar to Example 1 was carried out. The evaluation result is shown in FIG. 4.

### Example 7

Except for setting the oxygen introducing amount to be 1 L/min, the same condition as in Example 1 was used to reproduce the sintered body. The resistivity of the resulting sintered body was 0.96×10⁻³ Ω·cm, the relative density was 99.7%, and the average grain diameter was 30 μm. This sintered body was used to manufacture the target, the sputtering test similar to Example 1 was carried out. The evaluation result is shown in FIG. 4.

### Example 8

Except for setting the sintering temperature to be 1500° C. and setting the keeping period of time to be 2 hours, the same condition as in Example 1 was used to reproduce the sintered body. The resistivity of the resulting sintered body was 1.32×10⁻³ Ω·cm, the relative density was 98.4%, and the average grain diameter was 50 μm. This sintered body was used to manufacture the target, the sputtering test similar to Example 1 was carried out. The evaluation result is shown in FIG. 4.

### Comparative Example 1

Except for setting the sintering temperature to be 1550° C. and setting the keeping period of time to be 2 hours, the same condition as in Example 1 was used to reproduce the sintered body. The resistivity of the resulting sintered body was 1.28×10⁻³ Ω·cm, the relative density was 97.8%, and the average grain diameter was 72 μm. This sintered body was used to manufacture the target, the sputtering test similar to Example 1 was carried out. The evaluation result is shown in FIG. 4.

### Example 9

Except for setting the sintering temperature to be 1200° C., setting the oxygen introducing amount to be 10 L/min, and setting the keeping period of time to be 16 hours, the same condition as in Example 1 was used to reproduce the sintered body. The resistivity of the resulting sintered body was 1.9×10⁻³ Ω·cm, the relative density was 99.5%, and the average grain diameter was 5 μm. This sintered body was used to manufacture the target, the sputtering test similar to Example 1 was carried out. The evaluation result is shown in FIG. 4.

### Comparative Example 2

Except for absence of the hermetically sealed container shown in FIGS. 2 and 3, setting the sintering temperature to be 1400° C., and setting the oxygen introducing amount to be 30 L/min, the same condition as in Example 1 was used to reproduce the sintered body. The resistivity of the resulting sintered body was 2.03×10⁻³ Ω·cm, the relative density was 99.2%, and the average grain diameter was 60 μm. This sintered body was used to manufacture the target, the sputtering test similar to Example 1 was carried out. The evaluation result is shown in FIG. 4.

Further, the sintered body was cut in the thickness direction, and the distribution of the resistivity in the cut surface was measured in a range of 330 mm horizontal and 25 mm thickness. The results are shown in FIG. 5(B). It was confirmed that the variation percentage was significantly high, specifically, 92.1% and thus the resistivity was substantially evenly distributed. It should be noted that the variation percentage was calculated by subtracting an average value from a difference between the maximum value and the minimum value of the resistivity at each point.

### Comparative Example 3

Except for setting the weight ratio of ZnO:Ga203 to be 95:5 and setting the sintering temperature to be 1500° C., the same condition as in Example 1 was used to reproduce the sintered body. The resistivity of the resulting sintered body was several M Ω·cm, the relative density was 81.6%, and the average grain diameter was 2 μm. This sintered body was used to manufacture the target, the sputtering test similar to Example 1 was carried out. The evaluation result is shown in FIG. 4.

As will be clear from the above-mentioned results, it was confirmed that, regarding the sintered body produced under the processing condition of from 1200 to 1500° C. after the compact was housed in the inside of the container, each of the sintered bodies (Examples 1 to 9) each obtained in such a manner that the oxygen is introduced before the sintering temperature and the introduction of the oxygen was stopped during temperature-lowering has the resistivity of 2×10⁻³ Ω·cm, the relative density of 98% or more, and the average grain diameter of 50 μm or less. Further, regarding any of the sintered bodies, defects of the target surface, such as nodules, were not confirmed.

Regarding the sintered body according to Comparative example 1, the grain coarsening occurred and a high relative density of 98% or more could not be obtained. This could be due to the fact that the sintering temperature was high, specifically, 1550° C. The formation of nodules and the like can be considered to result from an occurrence of an abnormal electrical discharge due to low sintered density.

Regarding the sintered body according to Comparative example 2, the compact was not housed in the inside of the container and was sintered with the compact being directly exposed to the inside of the furnance, and hence, a significantly large resistivity distribution due to the influence of the temperature of the inside of the furnance was confirmed. As a result, a significantly large number of surface defects such as nodules and the like were confirmed.

Regarding the sintered body according to Comparative example 3, the mixing ratio of gallium oxide was high, specifically, 5 wt %, and hence the resistivity was significantly high, specifically, several M Ω. Therefore, in DC sputtering, a charge up occurred and thus continous sputtering was impossible. Further, it was confirmed that it was difficult to obtain the sintered body having the higher density.

Although the embodiment of the present invention has been described, it is needless to say that the present invention is not limited thereto, and various modifications thereof can be made on the basis of the technical idea of the present invention.

For example, a plurality of containers may be installed in the inside of the sintering furnace, and compacts may be housed in the plurality of containers so that the compacts can be subjected to the sintering process simultaneously. With this, it is possible to achieve an improvement of productivity. In this case, the oxygen introduction line is provided to each of the containers.

Further, although the introduction of the oxygen into the inside of the container is set to be stopped in the temperature lowering step during sintering in the above-mentioned embodiment, introduction of non-oxidizing gas such as nitrogen or argon into the inside of the container may be performed at the same time when the introduction of the oxygen is stopped.

### DESCRIPTION OF SYMBOLS

10 . . . sintering furnace
11 . . . furnance main body
12 . . . heater
20 . . . container
31 . . . piping
S1 . . . compact
S2 . . . sintered body

1. A method of producing a sintered body for a ZnO—Ga₂O₃-based sputtering target, comprising:
forming a powder mixture of a zinc oxide powder and a gallium oxide powder;
housing the compact of the powder mixture in an inside of a container to be installed in an inside of a sintering furnace;
raising a temperature of the compact up to a sintering temperature of not less than 1200° C. but not more than 1500° C. while introducing oxygen into the inside of the container;
keeping the sintering temperature under a state in which the oxygen is introduced into the inside of the container; and
lowering a temperature of the inside of the furnance under a state in which the introduction of the oxygen into the inside of the container is stopped.

2. The method of producing a sintered body for a ZnO—Ga₂O₃-based sputtering target, according to claim 1, wherein
a flow rate of the oxygen to be introduced into the inside of the container is 20 L/min or less.

3. The method of producing a sintered body for a ZnO—Ga₂O₃-based sputtering target, according to claim 1, wherein
a mixing ratio of the gallium oxide powder is 2 wt % or less.

4. The method of producing a sintered body for a ZnO—Ga₂O₃-based sputtering target, according to claim 1, wherein
the container includes a plurality of containers installed in the inside of the sintering furnace so that compacts each housed in the plurality of containers are sintered simultaneously.

5. A sintered body for a ZnO—Ga₂O₃-based sputtering target, comprising a sintered body of a powder mixture of a zinc oxide powder and a gallium oxide powder, and having
a relative density of 98% or more,
an average grain diameter of 50 μm or less, and
a resistivity of 2×10⁻³ Ω·cm or less.

6. A sintered body for a ZnO—Ga₂O₃-based sputtering target, according to claim 5, wherein
a distribution of resistivity in each of an in-plane direction and a depth direction of the sintered body is 20% or less.
